(19) United States
(12) Patent Application Publication
(10) Pub. No.: US 2009/0257175 A1
(43) Pub. Date: Oct. 15, 2009

(54) HOUSING AND METHOD FOR FABRICATING THE SAME

(75) Inventors: ZHENG SHI, Shenzhen City (CN); CHIH-CHIANG CHANG, Shindian (TW)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/141,239

(22) Filed: Jun. 18, 2008

(30) Foreign Application Priority Data
Apr. 11, 2008 (CN) 200810301104.0

(51) Int. Cl. H05K 5/00; H05K 7/00; H05K 7/18

(52) U.S. Cl. 361/679.01; 29/592; 29/592.1

(57) ABSTRACT

A housing (10) of portable electronic devices includes a base (11) and a paint layer (12). The base is made of metal and includes patterns (115) formed thereon. The paint layer is formed on the base and covering the patterns. A method for fabricating the housing is also provided.

### BACKGROUND

1. Field of the Invention

The present invention relates to housings, particularly to a housing of portable electronic device and a method for fabricating the same.

2. Description of Related Art

Nowadays, portable electronic devices such as mobile phones, laptops and personal digital assistants (PDA) are widely used. Many portable electronic devices have their external appearance decorated by colorized paint. In fabrication, paint is spread onto a surface of a portable electronic device to form a paint layer to achieve a colorized appearance. However, since the paint layer is usually smooth, portable electronic devices having a paint layer are relatively hard to firmly hold.

Therefore, a new housing and a new method for fabricating the same are desired in order to overcome the above-described shortcomings.

### BRIEF DESCRIPTION OF THE DRAWINGS

Many aspects of the present housing and method for fabricating the same can be better understood with reference to the following drawings. The components in the various drawings are not necessarily drawn to scale, the emphasis instead being placed upon clearly illustrating the principles of the present housing and method for fabricating the same. Moreover, in the drawings, like reference numerals designate corresponding parts throughout the diagrams.

FIG. 1 is a cross-sectional view of a housing according to an exemplary embodiment.

FIG. 2 is a flow chart of a method according to an exemplary, which is configured for fabricating the housing shown in FIG. 1.

### DETAILED DESCRIPTION OF THE EXEMPLARY EMBODIMENT

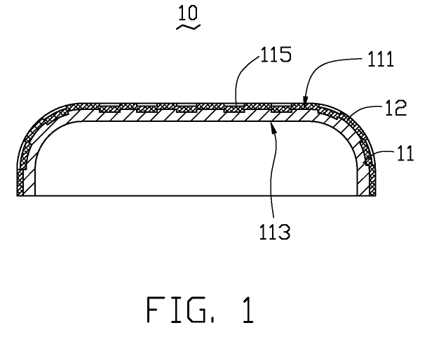

Referring to FIG. 1, a housing 10 according to an exemplary embodiment is shown. The housing 10 may be used in a portable electronic device, such as a mobile phone, a personal digital assistant (PDA), a laptop, etc. The housing 10 includes a base 11 and a paint layer 12 formed on the base 11.

The base 11 is a board made of at least one material selected from the group consisting of stainless steel, aluminum, aluminum alloy, titanium, titanium alloy, etc. The base 10 includes an outer surface 111 and an inner surface 113. Patterns 115, such as leather veins, can be formed on the outer surface 111 by chemical etching or laser etching.

The paint layer 12 can be made of a coating having a leather texture and formed on the outside surface 111 of the base 10 using baking varnish. The paint layer 12 covers the patterns 115 and achieves a non-flat surface of different heights according to undulations of the patterns 115. Thus, the patterns 115 cooperate with the paint layer 12 to form a three dimension visual effect that having a textured leather feel. Furthermore, the textured leather feel of the outer surface 111 improves a user's ability to grip the portable electronic device.

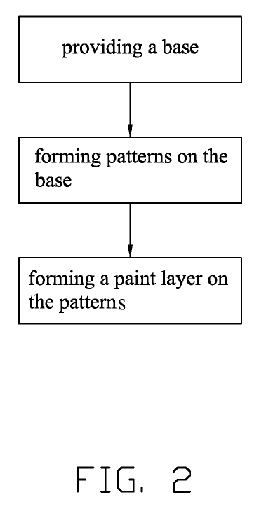

Referring to FIG. 2, a method for fabricating the housing 10 according to an exemplary embodiment is shown.

First, a base 11 is provided. The base 11 can be made of at least one material selected from the group consisting of stainless steel, aluminum, aluminum alloy, titanium, titanium alloy, etc.

Second, predetermined patterns 115, such as leather veins, can be formed on a surface of the base 11 by chemical etching or laser etching to roughen the surface 11.

Third, a paint layer 12 made of leather coating is formed on the outside surface 111 of the base 10 using baking varnish. The paint layer 12 covers the patterns 115 and achieves a non-flat surface of different heights according to undulations of the patterns 115. A housing 10 is completed. The patterns 115 cooperate with the print layer 12 to form an attractive three-dimensional visual effect, for example, a leather appearance.

The method for fabricating the housing 10 is simple and costs less. The patterns 115 of the housing 10 improve a users ability to grip the portable electronic devices. Furthermore, the patterns 115 cooperate with the paint layer 12 to improve the external appearance of the housing 10.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A housing of a portable electronic device, comprising:
a metal base including patterns formed thereon; and
a paint layer formed on the base and covering the patterns.

2. The housing as claimed in claim 1, wherein the base is made of at least one metal selected from the group consisting of stainless steel, aluminum, aluminum alloy, titanium and titanium alloy.

3. The housing as claimed in claim 1, wherein the base includes an outside surface and an inner surface, and the patterns are formed on the outside surface.

4. The housing as claimed in claim 1, wherein the patterns are leather veins.

5. The housing as claimed in claim 1, wherein the patterns are formed by etching.

6. The housing as claimed in claim 1, wherein the paint layer is a leather coating.

7. The housing as claimed in claim 1, wherein the paint layer has different heights according to undulations of the patterns.

8. A method for fabricating a housing of portable electronic devices, comprising the steps of:
providing a base;
forming patterns on a surface of the base; and
forming a paint layer on the patterns.

9. The method as claimed in claim 8, wherein the base is made of at least one material selected from the group consisting of stainless steel, aluminum, aluminum alloy, titanium and titanium alloy.

10. The method as claimed in claim 8, wherein the base includes an outside surface and an inner surface, and the step of forming the patterns is carried out on the outside surface.

11. The method as claimed in claim 8, wherein the step of forming the patterns further comprises forming leather veins.

12. The method as claimed in claim 8, wherein the step of forming the patterns uses etching.

13. The method as claimed in claim 8, wherein the paint layer is made of a leather coating.

14. The method as claimed in claim 8, wherein the paint layer has different heights according to undulations of the patterns.
